(19) United States
(12) Patent Application Publication
(10) Pub. No.: US 2009/0103249 A1
(43) Pub. Date: Apr. 23, 2009

(54) Integrated Frame for Monocoque Housing

(76) Inventors: Daniella STRAT, Sound Beach, NY (US); David Bellows, Wantagh, NY (US)

Correspondence Address: Fay Kaplun & Marcin, LLP/ Motorola, 150 Broadway Suite 702, New York, NY, 10038, US

(21) Appl. No.: 11/861,823

(22) Filed: Sep. 26, 2007

(51) Int. Cl. G06F 1/16; H05K 5/02

(52) U.S. Cl. 361/679.01

(57) ABSTRACT

A monocoque housing comprises a main housing and an integrated unit. The main housing includes an opening leading to a recess within the main housing. The integrated unit includes a frame and an end cap being received by the main housing through the opening so that, when assembled, the end cap occupies the opening and the frame is received within the recess.

### FIELD OF THE INVENTION

The present invention relates generally to an integrated frame for monocoque housing. Specifically, an end cap is integrated into a frame portion of the monocoque housing.

### BACKGROUND

A housing for a mobile electronic device has typically been a “clamshell” approach. In the clamshell housing, a top portion and a bottom portion are assembled to create the overall housing. Electronic components may be encased therein between the top and bottom portions. However, the clamshell approach may increase an overall product size, consequently increasing a volume and weight as well. In addition, the assembling for the clamshell housing may be complex with breakable parts that are not as robust as other housing types.

The marketplace for mobile unit technology continually drives to miniaturize the unit while including as many functionalities and increasing sturdiness. In order to improve upon an overall product size, volume, weight, and complexity, the housing for a mobile electronic device may utilize a monocoque housing approach. The monocoque housing design consists of a main housing, an end cap, and a frame. The electronic components may be assembled to the frame. The frame then slides into the main housing. The end cap closes off the open side in which the frame was received. Locking mechanisms such as screws may then fasten the assembly, typically from both sides to steady the frame in the main housing and to hold the end cap in place.

### SUMMARY OF THE INVENTION

The present invention relates to a monocoque housing comprising a main housing and an integrated unit. The main housing includes an opening leading to a recess within the main housing. The integrated unit includes a frame and an end cap being received by the main housing through the opening so that, when assembled, the end cap occupies the opening and the frame is received within the recess.

### DESCRIPTION OF THE DRAWINGS

FIG. 1 shows a first perspective view of a bottom portion of a monocoque housing according to an exemplary embodiment of the present invention.

FIG. 2 shows a second perspective view of the bottom portion for a monocoque housing according to an exemplary embodiment of the present invention.

FIG. 3 shows a perspective view of a top portion for a monocoque housing according to an exemplary embodiment of the present invention.

FIG. 4 shows an aligned view of the bottom portion of FIG. 1 and the top portion of FIG. 3 according to an exemplary embodiment of the present invention.

FIG. 5 shows an assembled view of the bottom portion of FIG. 1 with the top portion of FIG. 3 according to an exemplary embodiment of the present invention.

### DETAILED DESCRIPTION

The exemplary embodiments of the present invention may be further understood with reference to the following description and the appended drawings, wherein like elements are referred to with the same reference numerals. The exemplary embodiments of the present invention describe a monocoque housing where an end cap and a frame are integrated. As will be described in detail below, the monocoque housing includes a bottom portion constituting a main housing and a top portion constituting the integrated end cap with frame. The monocoque housing may be used for any electronic device that may be portable or handheld such as a mobile unit, a pager, a cell phone, a radio frequency identification device, a scanner, a data acquisition device, an imager, etc. The monocoque housing and its constituent parts will be discussed in more detail below.

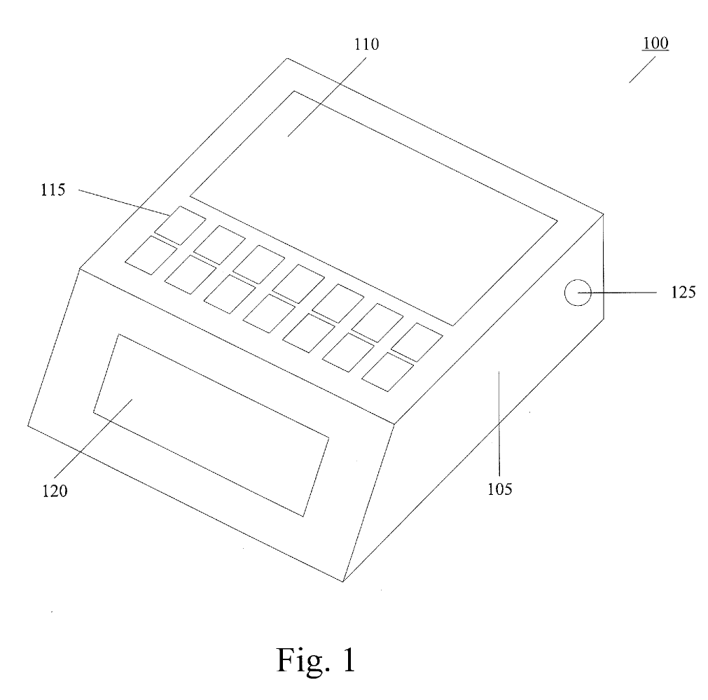

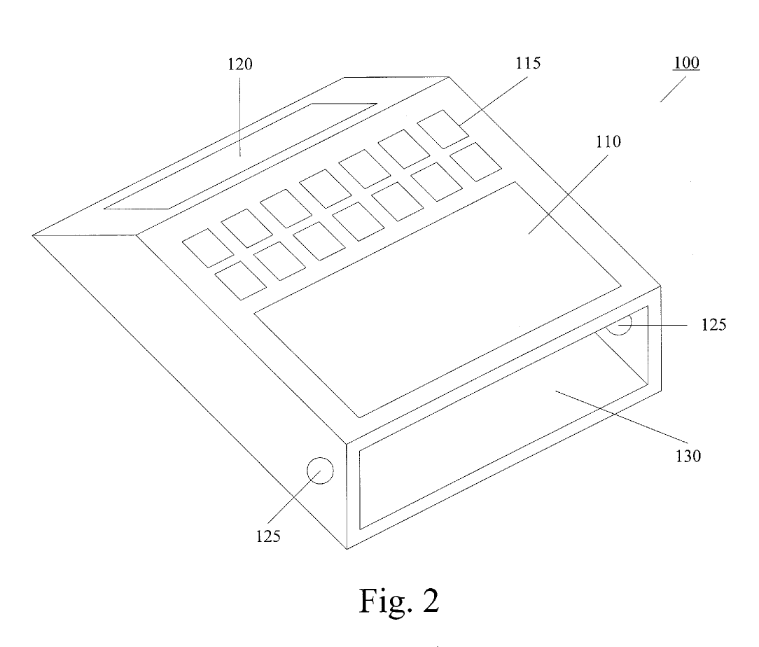

FIG. 1 shows a first perspective view of a bottom portion 100 of a monocoque housing according to an exemplary embodiment of the present invention. The bottom portion 100 constitutes a main housing for the monocoque housing. As will be described in further detail below, the bottom portion 100 may exhibit a majority of an outer surface area of the monocoque housing. Thus, the bottom portion 100 may include user interface components or components that require a line of sight from within the monocoque housing to an exterior location. As illustrated, the bottom portion 100 may include a bottom portion housing 105, a window 110, a data input arrangement 115, a scanner window 120, and a locking mechanism 125. The locking mechanism 125 will be discussed with reference to FIG. 2.

The bottom portion housing 105 may be a substantial shell in which the components of the bottom portion 100 are disposed on or within the bottom portion housing 105. As will be described in detail below, the bottom portion housing 105 may include an open side. Thus, if the bottom portion housing 105 is a substantially rectangular solid, the bottom portion housing 105 may include five faces. In the exemplary embodiment of FIG. 1, the bottom portion housing 105 may include five faces with a top face that is absent. It should be noted that the bottom portion housing 105 with an absent top face is only exemplary. For example, any other face of the bottom portion housing 105 may be absent. It should also be noted that a face being absent is only exemplary. For example, a face of the bottom portion housing 105 may include a hole. Thus, the face may be a substantial frame with a portion that is removed.

As discussed above, the components of the bottom portion 100 may be disposed at least partially within the bottom portion housing 105. For example, the display window 110, the data input arrangement 115, and the scanner window 120 may be disposed on a periphery of the bottom portion housing 105. The bottom portion 100 may also include connectors (e.g., wires) within the bottom portion housing 105. The connectors may electronically connect the data input arrangement 115 to circuitry contained in the bottom portion housing 105. Furthermore, the display window 110 may be a touch screen to enable a user to enter data inputs via touching an area of the touch screen. Thus, the connectors may electronically connect the display window 110 to the circuitry contained in the bottom portion housing 105.

The display window 110 may be a transparent panel to enable a user to view a display that is disposed beneath the display window 110. As will be discussed in detail below, a display may be part of an electronics stack that is aligned underneath the display window 110. As discussed above, the display window 110 may work in conjunction with the display disposed underneath by acting as a touch screen that receives touch inputs. Because the display window 110 is used primarily for viewing purposes, the display window 110 may be tinted to facilitate an efficient viewing of the data shown on the display. For example, the display window 110 may be tinted blue when a backlight is used, may be tinted yellow when viewed in sunlight, etc.

The data input arrangement 115 may be, for example, a key pad. The key pad may include any number of keys. For example, the key pad may be a QWERTY keypad that includes the English alphabet. In another example, the key pad may be a numeric key pad. In yet another example, the key pad may include the QWERTY key pad and the numeric key pad. It should be noted that the data input arrangement 115 may further include keys disposed on other sides of the bottom portion housing 105 (e.g., side).

The scanner window 120 may be substantially similar in function to the display window 110. That is, the scanner window 120 may be a transparent panel. Furthermore, the scanner window 120 may provide a line of sight from a scanning engine disposed within the bottom portion housing 105 to an object. The scanner window 120 may also be tinted to facilitate a proper scan of an object by the scanning engine. It should be noted that the scanning engine may be part of the bottom portion 100 or as part of the electronics stack that also includes the display discussed above.

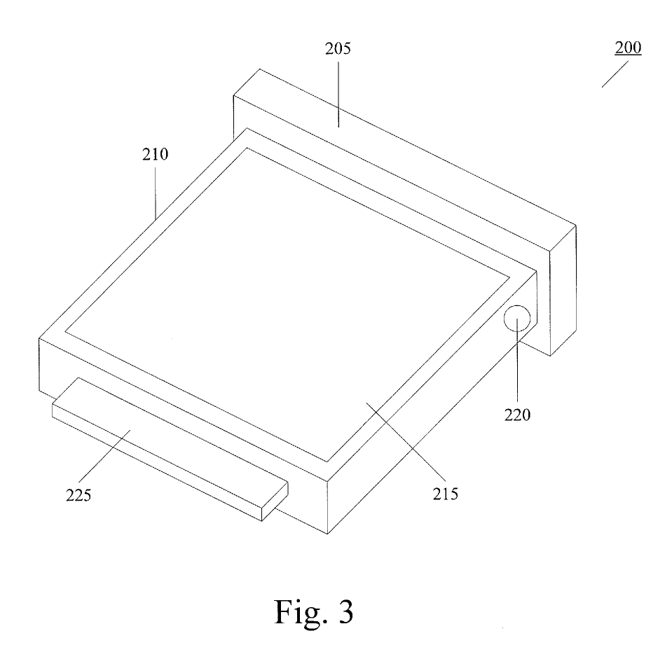

FIG. 2 shows a second perspective view of the bottom portion 100 for a monocoque housing according to an exemplary embodiment of the present invention. The second perspective view of the bottom portion 100 illustrates substantially the same components discussed above with reference to the first perspective view of FIG. 1. In addition, the second perspective view illustrates an opening 130. The opening 130 may receive a top portion of the monocoque housing. The top portion will be discussed in detail below with reference to FIG. 3.

As discussed above, the opening 130 may be from an absence of a side of the bottom portion 100 being a substantially rectangular solid. The opening 130 may lead to a recess within the bottom portion housing 105. The recess may extend substantially an entire length of the bottom portion housing 105. As will be discussed in further detail below, the top portion may include a frame that occupies the recess.

The locking mechanism 125 may enable the top portion of the monocoque housing to be locked with the bottom portion 100. The locking mechanism 125 may be any device that provides a locking feature. The locking mechanism 125 may be mechanical, electronic, and/or a combination thereof. For example, as a mechanical lock, the locking mechanism 125 may be a screw hole, a latch, etc. In another example, as an electronic lock, the locking mechanism 125 may be a solenoid. In yet another example, the locking mechanism 125 may be an adhesive. As illustrated, the locking mechanism 125 is disposed on both sides of the bottom portion housing 105. Furthermore, the locking mechanism 125 may extend from an outer periphery to an inner periphery (e.g., recess) of the bottom portion housing 105. It should be noted that the disposition of the locking mechanism 125 according to the present invention is only exemplary. For example, the locking mechanism 125 may be disposed wholly within the bottom portion housing 105, wholly outside the bottom portion housing 105, on a front side of the bottom portion housing 105, on a back side of the bottom portion housing 105, etc.

FIG. 3 shows a perspective view of a top portion 200 for a monocoque housing according to an exemplary embodiment of the present invention. As illustrated, the top portion 200 may be an integrated portion that includes an end cap 205 and a frame 210. That is, the top portion 200 may be manufactured as a singular unit. It should be noted that the end cap 205 and the frame 210 may be manufactured separately. Subsequently, the two components may be permanently affixed to each other. The top portion 200 may include the end cap 205, the frame 210, an electronics stack 215, a corresponding locking mechanism 220, and an electrical contact 225.

The end cap 205 may be a complementary component to the bottom portion 100. That is, when the top portion 200 is assembled with the bottom portion 100, the end cap 205 may cover the opening 130. When the monocoque housing is assembled, the end cap 205 may be disposed in a variety of positions. For example, the end cap 205 may be incorporated with the frame 210 so that a substantial T-shape is created. That is, the end cap 205 may include edges that go beyond a cross section of the frame 210. Thus, the end cap 205 may be external to the bottom portion 100 and merely covering the opening 130. The end cap 205 may be flush with a periphery of the bottom portion housing 105. Therefore, the periphery of the monocoque housing may be created. In another example, the end cap 205 may be sized so that the end cap 205 fits into the opening 130. The end cap 205 may be received in the opening 130 so that a top side of the end cap 205 is flush with a top side of the bottom portion housing 105.

The frame 210 may be a portion of the top portion 200 that is received by the bottom portion 100 through the opening 130. As discussed above, the opening 130 may lead to a recess in the bottom portion housing 105. The frame 210 may occupy the recess when the monocoque housing is assembled. Because the frame 210 is received by the bottom portion 100, the frame 210 may be equipped with a guiding mechanism so that the assembling of the top portion 200 with the bottom portion 100 may be done correctly. That is, the guiding mechanism may ensure a proper orientation and positioning of the frame 210 within the bottom portion housing 105. The guiding mechanism may be, for example, rails and channels.

The frame 210 may include the electronics stack 215. The electronics stack 215 may include the electrical components of the electronic device that is encased in the monocoque housing. For example, the electronics stack 215 may include a processor, a memory, a network device, an antenna, a scanning engine, etc. As discussed above, the electronics stack 215 may also include a display. The proper orientation discussed above may be so that a first condition is that the display of the electronics stack 215 is aligned with the display window 110.

The corresponding locking mechanism 220 may be a complementary component for the locking mechanism 125 of the bottom portion 100. For example, if the corresponding locking mechanism 220 may also be a screw hole. When the locking mechanism 125 which is a screw hole and the corresponding locking mechanism 220 which is also a screw hole are aligned, a screw may be used to lock the top portion 200 to the bottom portion 100. In another example, the corresponding locking mechanism 220 may be a recess in which a latch is received. In yet another example, the corresponding locking mechanism 220 may be a magnet for a solenoid. Thus, the corresponding locking mechanism 220 may be disposed in or on any location of the top portion 200 to complement the locking mechanism 125.

The electrical contacts 225 may electrically couple the top portion 200 with the bottom portion 100. Specifically, the electronics stack 215 may be coupled to components of the bottom portion 100 such as the data input arrangement 115 and the display 110. For example, the data input arrangement 115 and the display 110 may be connected to circuitry contained within the bottom portion housing 105. The circuitry may further be equipped to receive the electrical contacts 225. Thus, when an input is entered via the data input arrangement 115 (e.g., keypad) or the display 110 (e.g., touch screen), the processor of the electronics stack 215 may receive the input. The electronics stack 215 may also contain a portable power supply. Thus, the data input arrangement 115, the display 110, the scanning engine (if contained in the bottom portion housing 105) may be powered from this power supply via the electrical contacts 225. The electrical contacts 225 may also serve to ensure that a proper orientation is achieved. For example, the bottom portion housing 105 may include corresponding contacts that include a recess for receiving the electrical contacts 225.

It should be noted that the use of the electrical contacts 225 is only exemplary. For example, the device utilizing the monocoque housing may not include any electrical components on or in the bottom portion 100. Thus, an electrical connection may not be required. The electrical contacts 225 may be replaced with an extension which is received by a recess contained in the bottom portion housing 105. A proper orientation may be achieved in a substantially similar manner as with the electrical contacts 225.

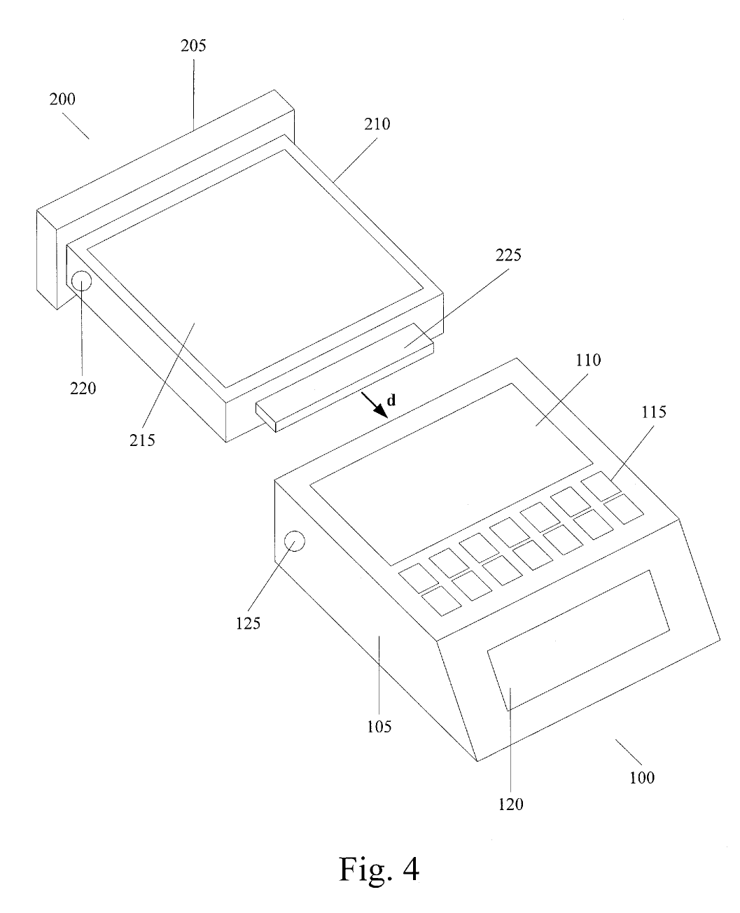

FIG. 4 shows an aligned view of the bottom portion 100 of FIG. 1 and the top portion 200 of FIG. 3 according to an exemplary embodiment of the present invention. As discussed above, the top portion 200 may be received by the bottom portion 100 by moving the top portion 200 in a direction d into the bottom portion 100. As illustrated, the electrical contacts 225 first enters the recess of the bottom portion housing 105 via the opening 130. The end cap 205 is a final component of the top portion 200 that contacts the bottom portion housing 105.

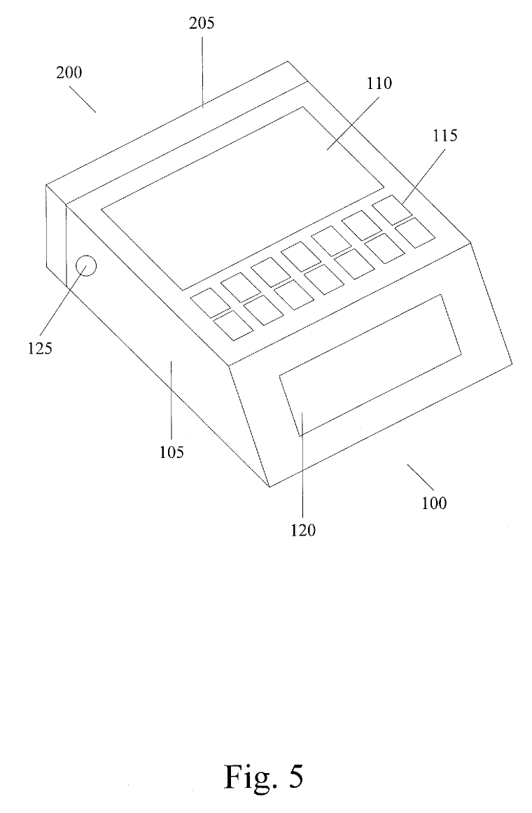

FIG. 5 shows an assembled view of the bottom portion 100 of FIG. 1 with the top portion 200 of FIG. 3 according to an exemplary embodiment of the present invention. The assembled view illustrates that the frame 210 with the electronics stack 215 and the electrical contacts 225 are wholly disposed within the bottom portion housing 105. Furthermore, the end cap 205 completes the monocoque housing by covering the opening 130 of the bottom portion housing 105. The top portion 200 is affixed to the bottom portion 100 via the locking mechanism 125. In addition, when assembled, the display of the electronics stack 215 is aligned with the display window 110. If the electronics stack 215 includes a scanning engine, the electronics stack 215 may also be aligned with the scanning window 120. The electrical contacts 225 is also coupled to corresponding contacts of the circuitry within the bottom portion housing 105.

The above described exemplary embodiments illustrate a monocoque housing in which a main housing (i.e., bottom portion 100) is assembled with a frame with an integrated end cap (i.e., top portion 200). The frame with integrated end cap reduces a total number of parts used to create the monocoque housing. The reduced number of parts also enables an easier assembly and a fewer amount of locking mechanisms (e.g., screws) and inherent redundancies in the conventional design are eliminated. Consequently, a smaller, lighter, and more tightly packaged monocoque housing results.

The frame with integrated end cap further provides additional benefits than the conventional monocoque housing design with a separate frame and a separate end cap. For example, the frame with integrated end cap enables a single part to be used for both internal and external features. Previously, the frame alone is internal to the monocoque housing while the end cap remained external. The end cap is also merely a cover for the main housing. As a result, the frame with integrated end cap reduces a number of tools for assembly, thereby reducing costs. Furthermore, hardware to attach the parts and a number of parts that are stored/inventoried may be reduced, thereby further reducing costs.

According to the exemplary embodiments of the present invention, the frame with integrated end cap occupies a position in both the internal (via the frame 210) and external (via the end cap 205) areas of the monocoque housing. The frame with integrated end cap may thus be used for additional purposes. In a first example, the integrated frame may be a lightpipe. A light emitting diode (LED) may be mounted on the electronics stack 215. The LED may direct light toward the end cap 205 to serve as an illumination device. In a second example, the integrated frame may be a sound port (e.g., microphone, speaker, etc.). The sound component may be mounted to the frame 210. Sound produced by the sound component may travel through a port disposed on the end cap 205. In a third example, the integrated frame may be a heat exchanger. The frame 210 and the end cap 205 may be manufactured of a thermally conductive material. Internal heat that is generated may be conducted from the internal component (i.e., frame) to the external component (i.e., end cap) so that heat escapes. In a fourth example the integrated frame may be an electrical connector (e.g., input/output). A physical connector may be mounted to the end cap 205 so that a direct connection to the electronics stack 215 may be established. An embedded connector may link the physical connector to the electronics stack 215.

It should be noted that other exemplary embodiments exist for the monocoque housing including a main housing and an frame with integrated end cap. For example, a disposition of the components of the device may be different. The scanning window 120 may be included in the end cap 205. Thus, the scanning engine may be disposed partially in the frame 210 and the end cap 205. In another example, the frame with integrated end cap may be received by the main housing through the opening 130 that is disposed on other faces of the main housing. The opening 130 may be located on a side surface or a bottom surface of the main housing. Thus, the frame with integrated end cap may be received by the main housing at those locations.

It will be apparent to those skilled in the art that various modifications may be made in the present invention, without departing from the spirit or scope of the invention. Thus, it is intended that the present invention cover the modifications and variations of this invention provided they come within the scope of the appended claims and their equivalents.

What is claimed is:

1. A monocoque housing, comprising:
a main housing including an opening leading to a recess within the main housing; and
an integrated unit including a frame and an end cap being received by the main housing through the opening so that, when assembled, the end cap occupies the opening and the frame is received within the recess.

2. The monocoque housing of claim 1, wherein the main housing further includes a display window, a data input arrangement, and a scanner window.

3. The monocoque housing of claim 2, wherein the frame includes an electronics stack.

4. The monocoque housing of claim 3, wherein the electronics stack includes a display and a scanning engine.

5. The monocoque housing of claim 4, wherein, when assembled, the display is aligned with the display window and the scanning engine is aligned with the scanner window.

6. The monocoque housing of claim 3, wherein the frame includes an electrical contact to couple to a circuitry of the main housing.

7. The monocoque housing of claim 6, wherein the circuitry is connected to the data input arrangement so that inputs received via the data input arrangement are forwarded to the electronics stack.

8. The monocoque housing of claim 7, wherein the electronics stack includes a processor to process the inputs.

9. The monocoque housing of claim 1, further comprising:
a locking mechanism to affix the integrated unit to the main housing.

10. The monocoque housing of claim 9, wherein the locking mechanism is one of screws, latches, a solenoid, an adhesive, and a combination thereof.

11. The monocoque housing of claim 1, wherein the end cap is one of received within the opening and covering the opening.

12. The monocoque housing of claim 11, wherein the end cap creates a flush periphery with the main housing.

13. An integrated unit, comprising:
a frame including an electronics stack; and
an end cap permanently affixed to the frame so that, when the integrated unit is received through an opening leading to a recess of a main housing for a monocoque housing, the frame is received within the recess and the end cap occupies the opening.

14. The integrated unit of claim 13, wherein the frame and the end cap are manufactured separately and subsequently affixed to each other.

15. The integrated unit of claim 13, further comprising:
an electrical contact electrically coupling to a corresponding contact disposed within the main housing.

16. The integrated unit of claim 13, further comprising:
a locking mechanism locking the integrated unit to the main housing.

17. The integrated unit of claim 16, wherein the locking mechanism is one of screws, latches, a solenoid, an adhesive, and a combination thereof.

18. The integrated unit of claim 13, wherein the end cap is configured to occupy the opening by one of being received in the opening and covering the opening.

19. The integrated unit of claim 13, wherein, when the integrated unit is received by the main housing, an overall flush periphery of the monocoque housing is created.

20. A monocoque housing, comprising:
a main housing including an opening leading to a recess within the main housing; and
an integration means for being received by the main housing through the opening, the integration means including a frame and an end cap, the end cap occupying the opening and the frame being received within the recess when the monocoque housing is assembled.
